(19) United States
(12) Patent Application Publication
(10) Pub. No.: US 2025/0279328 A1
(43) Pub. Date: Sep. 4, 2025

(54) CHIP PACKAGE ASSEMBLY WITH ON-PACKAGE CONTAINMENT SYSTEM

(71) Applicant: Advanced Micro Devices, Inc., Santa Clara, CA (US)

(72) Inventors: Mark STEINKE, Austin, TX (US); Ethan CRUZ, Austin, TX (US); Girish Anant KINI, Santa Clara, CA (US); Joseph R. SIEGEL, Boxborough, MA (US); Vishal MEHMI, Austin, TX (US)

(21) Appl. No.: 18/592,284

(22) Filed: Feb. 29, 2024

(51) Int. Cl. H01L 23/367; H01L 23/00; H01L 23/373; H01L 23/498; H01L 25/065

(52) U.S. Cl. CPC H01L 23/3672; H01L 23/3736; H01L 23/49816; H01L 24/13; H01L 24/29; H01L 24/73; H01L 25/0652; H01L 2224/13009; H01L 2224/13025; H01L 2224/29005; H01L 2224/29011; H01L 2224/73153; H01L 2924/12; H01L 2924/15311; H01L 2924/181; H01L 2924/351

(57) ABSTRACT

A chip package, an electronic device, and methods for fabricating the same are disclosed herein. In one example, a chip package includes a package substrate, an integrated circuit (IC) die, and a stiffener. The IC die has a first height and is mounted on a top surface of the package substrate. The stiffener is mounted to the top surface of the package substrate. A cavity is disposed in the stiffener. The cavity has an opening formed through the stiffener that faces towards the IC die.

### TECHNICAL FIELD

Embodiments of the present disclosure generally relate to chip package assemblies and techniques for manufacturing the same. In particular, a chip package assembly is described herein having features that mitigate thermal interface materials (TIM) from leaking out of the contained areas.

### BACKGROUND ART

Electronic devices, such as tablets, computers, server, in-door telecom, out-door telecom, industrial computers, high performance computing data centers, copiers, digital cameras, smart phones, control systems and automated teller machines, among others, often employ electronic components which leverage chip package assemblies for increased functionality and higher component density. Conventional chip package assemblies include one or more stacked components such as integrated circuit (IC) dies, through-silicon-via (TSV) interposer, and a package substrate, with the chip package assembly itself stacked on a printed circuit board (PCB). The IC dies may include memory, logic, MEMS, RF or other IC devices.

Surface mounted components, such as capacitors, resistors, and the like, are often utilized in chip package assemblies in between the IC dies and the sides of the package. The surface mounted components are typically mounted to a package substrate laterally to the side and outward of the dies that are mounted to the package substrate. The surface mounted components are typically mounted between the dies and a stiffener, if utilized, which is generally mounted at the periphery of the of the package substrate. In some cases, a lid will be attached along the edges of the package substrate enclosing the IC dies, surface mounted components and, stiffener. Electronic devices, such as those listed above, produce heat and often require a heat sink to re-distribute the heat to allow for proper operating conditions for the electronic devices.

Often a thermal interface material (TIM) is utilized between the IC die and heat sink to provide a path for conducting the heat from the electronic device to the heat sink. The TIM may flow out from between the die and the heat sink into the region containing the surface mounted components between the IC die and the stiffener ring, which can short the components, and often the TIM overflows over the stiffener ring, leaking outside of the package. Each is considered a production defect and can adversely affect the electronic device or other nearby electronic devices and components. Thus, to minimize the potential for production defects due to TIM leaking from the space between the IC die and the heat sink, the space for surface mounted components must be sufficiently spaced from both the dies and the stiffener, or a foam or gasket must be applied around the outside of the package after assembly, which undesirably reduces the space available for dies or undesirably requires a larger package substrate, or in some instances an insufficient amount of TIM may be applied to the package.

Therefore, a need exists for an improved chip package assembly that mitigates leaking of excess TIM as compared what is conventionally available in the art.

### SUMMARY

A chip package, an electronic device, and methods for fabricating the same are disclosed herein. In one example, a chip package includes a package substrate, an integrated circuit (IC) die, and a stiffener. The IC die has a first height and is mounted on a top surface of the package substrate. The stiffener is mounted to the top surface of the package substrate. A cavity is disposed in the stiffener. The cavity has an opening formed through the stiffener that faces towards the IC die.

In another example, an electronic device is provided. The electronic device includes a package substrate, an integrated circuit (IC) die, a first electronic component, a heat sink, and a stiffener. The package substrate has a top surface. The IC die is mounted on the top surface of the package substrate. The stiffener is also mounted to the top surface of the package substrate. A first electronic component is mounted to a first region of the package substrate defined between the stiffener and the IC die. A cavity is formed in the stiffener. The cavity has an opening formed through the stiffener facing the first IC die. The heat sink is mounted on the first IC die. Thermal interface material (TIM) is disposed between the first IC die and the heat sink.

In yet another example, a method for fabricating a chip package assembly is provided that includes mounting an IC die to a top surface of a package substrate; attaching a stiffener to the top surface of the package substrate, the stiffener having a cavity facing the IC die; applying thermal interface material (TIM) to one of the top of the IC die or a bottom of a heat sink; and mounting the heat sink on the top of the IC die sandwiching the TIM therebetween.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional schematic view of an integrated circuit chip package mounted on a printed circuit board.

FIG. 2 is a partial schematic view of the integrated circuit chip package of FIG. 1.

FIG. 3 is a partial schematic view of a portion of another integrated circuit chip package.

FIG. 4 is a schematic top view of an example of a package substrate.

FIG. 5 is a flow diagram of a method for forming a chip package.

To facilitate understanding, identical reference numerals have been used, where possible, to designate identical elements that are common to the figures. It is contemplated that elements of one example may be beneficially incorporated in other examples.

### DETAILED DESCRIPTION

Embodiments of the disclosure generally provide chip package assemblies and package substrates that mitigate the potential for thermal interface materials (TIM) from leaking out from the area between the IC die and heat sink (bond line), contacting surface mounted components and/or overflowing over the stiffener ring. The chip package assemblies package substrates and techniques for manufacturing the same advantageously increase product yield by utilizing a containment structure within the stiffener ring to essentially prevent TIM from overflowing over the stiffener ring. Moreover, reliability is improved by insuring TIM does not contact the surface area outside of the package (i.e. outside of the stiffener), which reduces the potential for issues to other electronic devices and components outside of the electronic device on a printed circuit board (PCB). Other advantages include a more local containment area to the desired bond line, an economic solution avoiding the need for a separate containment fence, such as a foam or gasket applied outside the boundary of the stiffener, and improved package warpage resistance as the containment system is contained within a stiffener, all without increase in overall package substrate size.

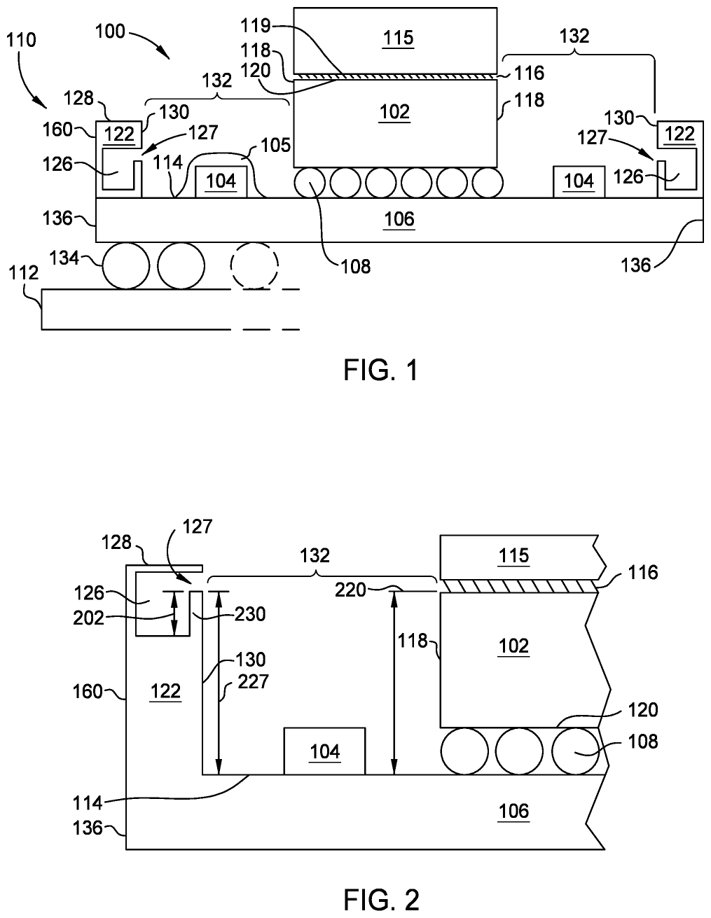

Turning now to FIG. 1, a cross section of an integrated circuit electronic device 110 is illustrated having an integrated circuit (IC) chip package assembly 100 mounted on a printed circuit board (PCB) 112 by solder balls 134. The PCB 112 and solder balls 134 are shown in phantom. The chip package assembly 100 generally includes one or more or more IC dies 102, a package substrate 106, one or more surface mounted components 104, and a stiffener 122. The stiffener 122 is configured to contain the movement of thermal interface material (TIM) 116, as further described below. The IC dies 102 may be programmable logic devices, such as field programmable gate arrays (FPGA), memory devices, optical devices, processors or other IC logic structures. The surface mounted components 104 may be one or more of a capacitors, diodes, resistors, inductors, or other suitable discrete circuit elements.

The IC dies 102 are connected directly to the package substrate 106, for example as flip chip ball grid array (FCBGA), ball grid array (BGA), wire bond and the like. In another example, one or more IC dies 102 of the chip package assembly 100 may be connected to the package substrate 106 via an interposer (not shown). It is contemplated that the chip package assembly 100 may have other configurations. Although one IC die 102 is shown in FIG. 1, the number of IC dies may range from one to as many as can be fit within the chip package assembly 100 in order to meet design criteria. A bottom of the IC die 102 is connected to a top surface 114 of the package substrate 106 by solder connections 108. The solder connections 108, such as micro-bumps, mechanically and electrically connect the circuitry of the IC die 102 to the circuitry of the package substrate 106.

The electronic device 110 includes a heat sink 115 positioned over the IC die 102. The heat sink 115 may be an active or a passive heat sink device. The heat sink 115 is used to dissipate the heat from an IC die, such as the IC die 102, such that the temperature of the IC die 102, the surface mounted components 104, and any other electronic devices mounted on the PCB 112 nearby to electronic device 110, can be maintained in the operating range of each component or device. The heat sink 115 may be attached to the PCB 112 via an interposer (not shown) or directly to the PCB 112.

The TIM 116 is disposed in the interstitial spaces between the bottom 119 of the heat sink 115 and the top surface 120 of the IC die 102. TIM 116 provides a path with increased conductivity to transfer the heat produced by a heat producing device, such as IC die 102, to a heat sink, such as heat sink 115, whereby the heat sink is configured to more efficiently dissipate heat. In some examples, the TIM 116 may be a liquid metal TIM. In other examples, the TIM 116 may be a thermal paste, a thermally conductive putty, or other types of TIM.

A TIM-containing stiffener 122 is generally mounted at an edge 136 along the periphery of the package substrate 106. The stiffener 122 often surrounds the IC die 102 and surface mounted components 104 continuously circumscribed along the outer edge of the chip package assembly 100. In the example illustrated in FIG. 1, an inner side wall 130 of the stiffener 122 faces and is spaced a distance apart from the IC die 102. An outer side wall 160 of the stiffener 122 faces away from the IC die 102 and forms the outer perimeter of the stiffener 122.

The stiffener 122 is attached to the top surface 114 of the package substrate 106. In some examples, the stiffener 122 is attached to the package substrate 106 by an adhesive material, such as an epoxy or other suitable bonding material. The stiffener 122 provides mechanical support which helps prevent the chip package assembly 100 from bowing and warping. The stiffener 122 may be a single layer structure or a multi-layer structure. The stiffener 122 may be made of ceramic, metal or other various inorganic materials, such as aluminum oxide (Al₂O₃), aluminum nitride (AlN), silicon nitride (SiN), silicon (Si), copper (Cu), aluminum (AI), and stainless steel, among other materials. The stiffener 122 can also be made of organic materials such as copper-clad laminate.

The surface mounted components 104 are coupled to the top surface 114 of the package substrate 106 in a region 132 defined between the inner side wall 130 of the stiffener 122 and the side 118 of the IC die 102. The surface mounted components 104 may be soldered to a conductor residing on or in the package substrate 106, and are coupled to the circuitry of the die 102 through the circuity of the package substrate 106.

The TIM 116 is often a viscous material, such as a liquid metal or a paste, which may leak out from the area below the heat sink 115 and inwardly bounded by the sides 118 of the IC die 102. The TIM 116 may thus flow into the region 132 between the IC die 102 and the stiffener 122. The TIM 116 may be an electrically conductive material which can short the surface mounted components 104. To prevent shorting, the surface mounted components 104 are covered by an encapsulant 105. The encapsulant 105 protects the materials and underlying components (for example, the surface mounted components 104) from oxidation, moisture, as well as from unintended electrical connections or shorting. The encapsulant 105 may be formed from dielectric materials such as epoxy, resin, or other polymers.

In conventional designs, an excess amount of the TIM 116 may flow into the region 132 filling the available space and overflowing over the top of conventional stiffeners. The TIM 116 may flow out of conventional chip package assemblies and onto the PCB, thereby potentially affecting the electrical connections made by the solder balls, or any other chip packages, components, or other electronic devices on the PCB.

To mitigate the undesirable movement of TIM in conventional chip package designs, the stiffener 122 includes a cavity 126 disposed within the stiffener 122. The cavity 126 has an opening 127 on the inner side wall 130 of the stiffener facing toward the IC die 102. The cavity 126 does not include an opening that penetrates the outer side wall 160 of the stiffener 122. The opening 127 allows the flow of TIM 116 to enter the cavity 126 and fill up the space of the cavity 126 instead of flowing over the top 128 of the stiffener 122, as would undesirably happen in conventional chip packages. Thus, the cavity 126 substantially prevents TIM 116 from leaking over the stiffener 122 and extending beyond the peripheral edge of the package substrate 106, by providing a space for the excess TIM 116 to go, which may inadvertently prevent the chip package assembly 100 from being utilized or otherwise disrupt the function of the electrical device 110 or other devices on the PCB 112. As the cavity 126 does not include an opening that penetrates the outer side wall 160 of the stiffener 122, TIM 116 within the cavity 126 cannot flow though the stiffener 122.

FIG. 2 is a partial sectional view of the chip package assembly 100 illustrating the stiffener 122 having the internal cavity 126 facing the region 132 with surface mount components 104 disposed next to the IC die 102 and the heat sink 115 in greater detail. The stiffener 122 may be configured in various embodiments having different sizes and shapes of the cavity 126, and the examples shown herein are not intended to limit the cavity 126 to a particular size or shape.

The opening 127 is formed in the inner side wall 130 of the stiffener 122 and provides access to the cavity 126 from the region 132. The bottom edge of the opening 127 is disposed at a height 227 about the top surface 114 of the package substrate 106, The portion of the inner side wall 130 disposed below the opening 127 creates a cavity in the region 132 containing the surface mount components 104. TIM 116 entering this cavity defined in the region 132 would move up the inner side wall 130 when encountering the stiffener 122 until the TIM 116 reaches the opening 127. Upon reaching the opening 127, the TIM 116 would flow through the opening 127 and into the cavity 126 formed in the stiffener 122 instead of continuing up the inner side wall 130 and overflowing the top 128 of the stiffener 122. The cavity 126 thus prevents the free flow of TIM 116 from flowing over the top 128 of the stiffener 122. In one example, the height of the bottom of the opening 127 has a height 227 that is greater than the height 220 from the top surface 114 of the package substrate 106 to the top of the IC die 102. In some examples, the TIM 116 is viscous and spreads quickly, thus a height 227 to the bottom of the opening 127 being greater than the height 220 of the top surface 120 of the IC die 102 ensures that the TIM 116 will first fill the space between the IC die 102 and the heat sink 115 before the TIM 116 flows into the cavity 126, while still inhibiting the flow of TIM 116 over the top 128 of the stiffener 122.

In another example, a side wall 230 of the cavity 126 has a length 202 defined below a bottom of the opening 127 is long enough to define a volume of the cavity 126 sufficiently great enough to contain the potential overflow of TIM 116, such that the TIM 116 does not flow over the top 128 of the stiffener 122. In yet another example, the height 227 of the bottom of the opening 127 is sufficiently tall enough to cause the TIM 116 to flow upward along the inner side wall 130 of the stiffener 122 and in contact with the side 118 of the die 102 and the stiffener 122 first, while the cavity 126 provides an safeguarding cavity to substantially prevent the TIM 116 from flowing over the top 128 of the stiffener 122. Thus, the height 227 of the opening 127 in the stiffener 122, along with the presence of the cavity 126, advantageously does not require the application of precise amounts of TIM 116 or other mitigation efforts to prevent TIM 116 from flowing out of the chip package assembly 100. In other examples, the side wall 230 of the cavity 126 is defined below a top of the opening 127, and in still other examples, a first portion of the side wall 230 of the cavity 126 is defined below a top of the opening 127 while a second portion of the side wall 230 of the cavity 126 is defined above a top of the opening 127 such that the opening 127 is in the middle of the side wall 230.

In one example, the side wall 230 and other structure bounding the cavity 126 is a part of the stiffener 122. This is, the side wall 230 and other structure bounding the cavity 126 is a contiguous single component with the stiffener 122. In another example, the side wall 230 is separately formed and attached to the stiffener 122. In yet another example, the side wall 230 and other structure bounding the cavity 126 are formed from a different material than the stiffener 122, and separately attached to the package substrate 106. In yet another example, the side wall 230 may be a separate component disposed or formed on the top surface 114 of the package substrate 106.

The remaining sides of cavity 126 may be formed within the stiffener 122. In some examples, the cavity 126 is formed prior attaching the stiffener 122 to the package substrate 106. In other examples, the cavity 126 may be formed after the stiffener has been attached to the package substrate 106.

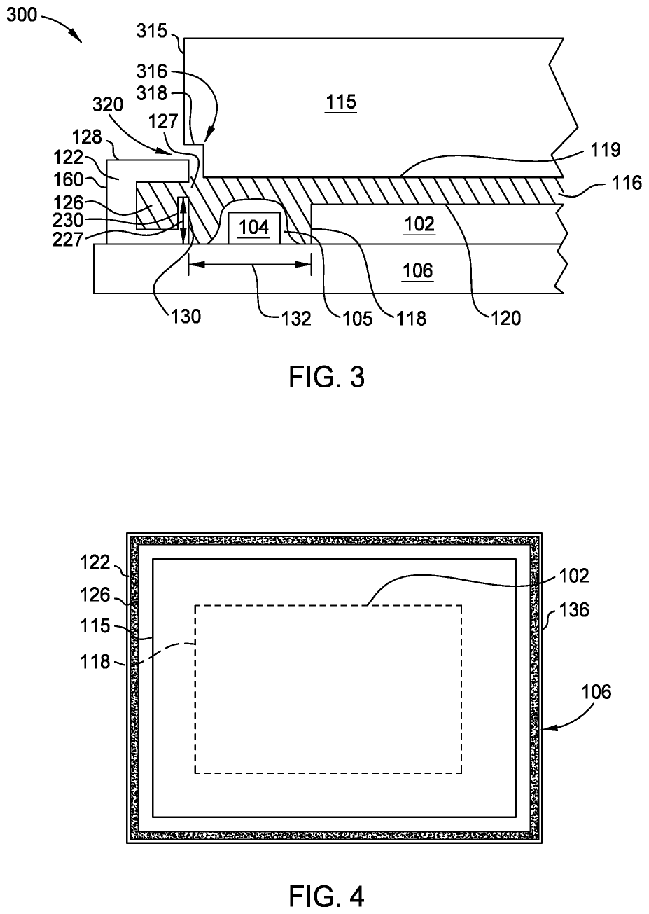

FIG. 3 is a partial schematic view of a portion of another integrated chip package assembly 300. Although only a portion of the chip package assembly 300 is illustrated in FIG. 3, the chip package assembly 300 is substantially the same as the chip package assembly 100 depicted in FIGS. 1-2, except wherein the heat sink 115 is configured to extend over the region 132 closer to the stiffener 122. FIG. 3 also depicts the relationship of the height 227 of the opening 127, the top 128 of the stiffener 122, the top surface 120 of the IC die 102, the bottom 119 of the heat sink 115, and the flow of the TIM 116 out from between the IC die 102 and the heat sink 115.

The heights 227 of the opening 127 in connection with the top 128 of the stiffener 122 and the height of the top surface 120 of the IC die 102 are selected to ensure that the TIM 116 is able to fill the gap formed between the IC die 102 and the heat sink 115, before any displacement of TIM 116 out from under the gap is preferentially directed toward the surface mounted components 104 and then inward through the opening 127 and into the cavity 126.

The number, location, and volume of the cavity 126 is selected to accommodate an expected amount of TIM 116 expected to be present after filling the gap between the IC die 102 and the heat sink 115. The location of the cavity 126 may be selected to promote a desired displacement of the TIM 116, such that the TIM 116 maintains contact with both the IC die 102 and heat sink 115, while the cavity 126 contains the overflow of the TIM 116, thus substantially preventing any TIM 116 from flowing over the top 128 of the stiffener. Accordingly, the cavity 126 advantageously prevents TIM 116 from being present outside of the chip package 100 or leaking onto the PCB 112, where the TIM 116 could potentially interfere with the chip package assembly 100 or any other electronic devices disposed on the PCB 112.

In some examples, the cross section of the cavity 126 may be rectangular. In other examples, the cross section of the cavity 126 may be round, oblong, or triangular. In some examples, the vertical cross-sectional area of the profile of the cavity 126 may greater than vertical cross-sectional area of the opening 127.

The heat sink 115 may be configured, such as shown in FIG. 3, to have sides 315 that extend beyond the sides of the sides 118 of the IC die 102 and over the surface mounted component 104 region 132. In some examples, the bottom 119 of the heat sink 115 may have a step 316 formed having an inverse shape of the corner of the stiffener 122. In some examples, the step 316 includes a roof 318 that faces the same direction as the bottom 119 of the heat sink 115. The roof 318 is generally above the top 128 of the stiffener 122. In some examples, the roof 318 horizontally overlaps the top 128 of the stiffener 122 such that the step 316, the roof 318 and top corner of the stiffener 122 form a tortuous gap 320. The tortuous gap 320 discourages the flow of TIM 116 therethrough. The size of the gap 320 relative to the size of the opening 127 also promotes capillary forces created by decreasing the space between the stiffener 122 and the heat sink 115 to leverage the surface tension of the TIM 116 to direct the excess TIM flow preferentially into the cavity 126 before flowing upwards over the top 128 of the stiffener 122.

Referring now to the schematic top view of one example of the package substrate 106 illustrated in FIG. 4, the stiffener 122 contiguously circumscribes the IC die 102 (shown in phantom below the heat sink 115) along the boundary of the package substrate 106. The heat sink 115 extends beyond the sides 118 of the IC die 102. Similarly, the cavity 126 (also shown in phantom) within the stiffener 122 contiguously circumscribes the IC die 102. The stiffener 122 and cavity 126 may be fabricated as described above, or in other manner in which stiffeners are used in package devices. In other examples, the stiffener 122 may be attached to the package substrate 106 in one or more areas along the periphery of the package substrate 106, wherein the cavity 126 is only in the areas immediately adjacent an IC die 102.

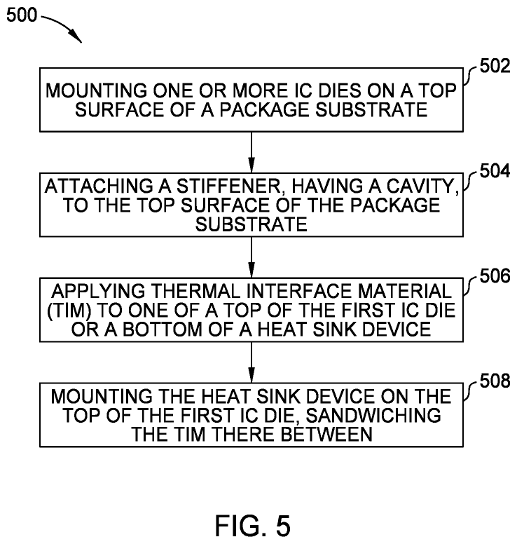

FIG. 5 is a flow diagram of a method 500 for forming a chip package, such as the chip package assemblies 100, 300 described above, among others. The method 500 begins at operation 502 by mounting one or more IC dies 102 on a top surface 114 of a package substrate 106. The IC dies 102 may be mounted to the top surface 114 of the package substrate 106 utilizing conventional or other suitable techniques, such as flip chip ball grid array (FCBGA), ball grid array (BGA), wire bond, or solder balls. In one example, a heat sink 115 is disposed over the first IC die 102, wherein the heat sink 115 over the first IC die 102 forms a gap between the heat sink 115 and the first IC die 102 defined by a first gap.

At operation 504, a stiffener 122, having an inner side wall 130 and a top 128, is attached to the top surface 114 of the package substrate 106 by an adhesive or other suitable method. In some examples, the stiffener 122 and a side of the heat sink 115 are in closer proximity than the stiffener 122 and a side of the IC die 102.

The stiffener 122 includes one or more internal containment areas (e.g., cavities 126) formed in the stiffener 122. The cavity 126 has an opening 127 formed through the inner side wall 130 of the stiffener 122 and facing a region 132 between the stiffener 122 and the IC die 102.

At operation 506, TIM 116 is applied to one of a top of the first IC die 102 or a bottom of a heat sink 115. At operation 508, the heat sink 115 is mounting on the top of the first IC die 102, sandwiching the TIM 116 therebetween. In some examples, some of the TIM 116 at operation 508 is squeezed out from between the first IC die 102 and the heat sink 115. In some examples, the portion of the TIM 116 squeezed out from between the first IC die 102 and the heat sink 115 extends into the region 132 between the stiffener 122 and the IC die 102 and enters the cavity 126 disposed in the stiffener 122 through the opening 127 of the cavity 126, thus substantially preventing the flow of TIM 116 over the top 128 of the stiffener 122.

Thus, chip package assemblies and package substrates that mitigate the potential for adhesive and/or underfill from contacting surface mounted components, along with techniques for fabricating the same, have been described above. The chip package assemblies, package substrates and techniques for manufacturing the same advantageously increase product yield, provide improved reliability by insuring consistent surface contact area between the package substrate and a stiffener, thus providing greater delamination resistance. Additionally, signal integrity is improved due to the closer spacing between surface mounted components and dies. Furthermore, the embodiments described above allow for smaller package substrate area requirements, and improved package warpage resistance as wider stiffeners may be accommodated due to smaller stiffener to die spacing requirements without an increase in package substrate size.

What is claimed is:

1. A chip package comprising:
a package substrate having a top surface;
an integrated circuit (IC) die having a first height mounted on the top surface of the package substrate;
a stiffener mounted to the top surface of the package substrate, the stiffener having a first side facing the IC die and a top; and
a cavity disposed in the stiffener, the cavity having an opening formed through the first side of the stiffener.

2. The chip package of claim 1, wherein the opening in the stiffener is on the first side of the stiffener and at a second height that is greater than the first height of the IC die.

3. The chip package of claim 1, wherein the stiffener is positioned at an outer border of the package substrate.

4. The chip package of claim 1, wherein a heat sink is disposed over the IC die.

5. The chip package of claim 4, wherein a space between the heat sink and the stiffener forms a tortuous gap.

6. The chip package of claim 5 further comprising:
a thermal interface material (TIM) is disposed between the IC die and the heat sink, the TIM extending preferentially into the cavity in the stiffener relative the tortuous gap.

7. The chip package of claim 5, wherein a distance across the opening is larger than a distance across the tortuous gap.

8. The chip package of claim 1, wherein the cavity extends away from the top of the stiffener.

9. An electronic device, comprising:
a package substrate having a top surface;
an integrated circuit (IC) die having a first height mounted on the top surface of the package substrate;
a stiffener mounted to the top surface of the package substrate, the stiffener having a first side and a top;
a first electronic component mounted to a first region of the package substrate defined between the stiffener and the IC die;
a cavity formed in the stiffener, the cavity having an opening formed through the stiffener facing the IC die;
a heat sink mounted on the IC die; and
a thermal interface material (TIM) disposed between the IC die and the heat sink.

10. The electronic device of claim 9, wherein the opening in the stiffener is on the first side of the stiffener and at a second height that is greater than the first height of the IC die.

11. The electronic device of claim 9, wherein the stiffener is positioned at an outer border of the package substrate.

12. The electronic device of claim 9, wherein a tortuous gap is defined between the heat sink and the stiffener.

13. The electronic device of claim 12 wherein the TIM extends preferentially into the cavity in the stiffener relative the tortuous gap.

14. The electronic device of claim 9, wherein the TIM extends into the cavity of the stiffener.

15. The electronic device of claim 9, wherein the cavity extends away from the top of the stiffener.

16. A method for fabricating a chip package assembly, the method comprising:
mounting an IC die to a top surface of a package substrate;
attaching a stiffener to the top surface of the package substrate, the stiffener having a cavity facing the IC die;
applying thermal interface material (TIM) to one of the top of the IC die or a bottom of a heat sink; and
mounting the heat sink on the top of the IC die sandwiching the TIM therebetween.

17. The method of claim 16 further comprising flowing the TIM into the cavity.

18. The method of claim 16, wherein mounting the heat sink on the top of the IC die further comprises:
forming a tortuous path between the heat sink and the stiffener.

19. The method of claim 18 further comprising preferentially flowing the TIM into the cavity relative to the tortuous path.

20. The method of claim 17, wherein flowing the TIM into the cavity further comprises flowing the TIM downward within the cavity.
